(19) United States
(12) Patent Application Publication
(10) Pub. No.: US 2017/0250694 A1
(43) Pub. Date: Aug. 31, 2017

(54) SYNCHRONIZATION CIRCUIT AND SEMICONDUCTOR APPARATUS INCLUDING THE SAME

(71) Applicant: SK hynix Inc., Icheon-si Gyeonggi-do (KR)

(72) Inventors: Da In IM, Icheon-si Gyeonggi-do (KR); Young Suk SEO, Icheon-si Gyeonggi-do (KR)

(21) Appl. No.: 15/193,357

(22) Filed: Jun. 27, 2016

(30) Foreign Application Priority Data
Feb. 29, 2016 (KR) 10-2016-0024352

(51) Int. Cl. H03L 7/081; G11C 29/00; G11C 7/22; H03L 7/18

(52) U.S. Cl. CPC H03L 7/0812; H03L 7/18; G11C 29/787; G11C 7/222

(57) ABSTRACT

A synchronization circuit may include: a delay line configured to delay a reference clock signal; a division circuit configured to generate a divided feedback clock signal by dividing a feedback clock signal at a division ratio which is set according to a division ratio control signal; a phase detection circuit configured to generate a phase detection signal by detecting the phase of the divided feedback clock signal based on the reference clock signal; and a delay line control circuit configured to control a delay time of the delay line according to the phase detection signal and the divided feedback clock signal.

### CROSS-REFERENCES TO RELATED APPLICATION

The present application claims priority under 35 U.S.C. § 119(a) to Korean application number 10-2016-0024352, filed on Feb. 29, 2016, in the Korean Intellectual Property Office, which is incorporated herein by reference in its entirety.

### BACKGROUND

1. Technical Field

Various embodiments relate to a semiconductor circuit, and more particularly, to a synchronization circuit and a semiconductor apparatus including the same.

2. Related Art

A semiconductor apparatus may use a synchronization circuit, for example, a DLL (Delay Locked Loop), in order to compensate for a timing difference between an external clock signal and an internal clock signal.

The DLL may compensate for a time delay difference between a reference clock signal or an external clock signal and a feedback clock signal obtained by passing the external clock signal through a replica delay circuit.

With an increase in the frequency of the reference clock signal, the DLL may not secure a sufficient operation timing margin, which makes it possible to degrade the operation stability of a system to which the DLL is applied.

### SUMMARY

Various embodiments are directed to a synchronization circuit capable of increasing operation stability and a semiconductor apparatus including the same.

In an embodiment of the present disclosure, a synchronization circuit may include: a delay line configured to delay a reference clock signal; a division circuit configured to generate a divided feedback clock signal by dividing a feedback clock signal at a division ratio which is set according to a division ratio control signal; a phase detection circuit configured to generate a phase detection signal by detecting the phase of the divided feedback clock signal is based on the reference clock signal; and a delay line control circuit configured to control a delay time of the delay line according to the phase detection signal and the divided feedback clock signal.

In an embodiment of the present disclosure, a semiconductor apparatus may include: a memory circuit configured to perform a data output operation according to a DLL clock signal; and a synchronization circuit configured to generate the DLL clock signal by delaying a reference clock signal through a delay line, and adjust a delay time of the delay line according to a divided feedback clock signal obtained by dividing the feedback clock signal.

### BRIEF DESCRIPTION OF THE DRAWINGS

Features, aspects, and embodiments are described in conjunction with the attached drawings, in which:

FIG. 1 is a diagram illustrating a configuration of a synchronization circuit according to an embodiment;

FIG. 2 is a diagram illustrating a configuration of a division circuit of FIG. 1;

FIG. 3 is an operation timing diagram of the synchronization circuit according to an embodiment;

FIG. 4 is a diagram illustrating a configuration of a synchronization circuit according to another embodiment;

FIG. 5 is a diagram illustrating a configuration of a synchronization circuit according to another embodiment; and

FIG. 6 is a diagram illustrating a configuration of a semiconductor apparatus according to another embodiment.

FIG. 7 illustrates a block diagram of a system employing a semiconductor device in accordance with the various embodiments discussed above with relation to FIGS. 1-6.

### DETAILED DESCRIPTION

Hereinafter, a synchronization circuit and a semiconductor apparatus including the same according to the present disclosure will be described below with reference to the accompanying drawings through example embodiments.

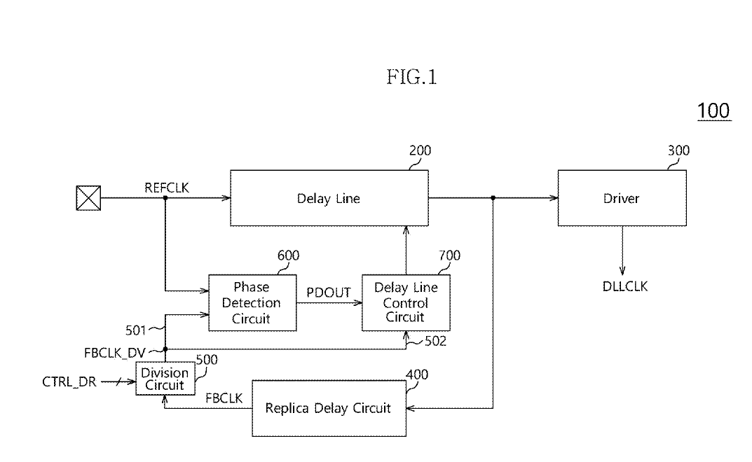

As illustrated in FIG. 1, a synchronization circuit 100 according to an embodiment may include a delay line 200, a driver 300, a replica delay circuit 400, a division circuit 500, a phase detection circuit 600 and a delay line control circuit 700.

The delay line 200 may delay a reference clock signal REFCLK.

The driver 300 may drive an output signal of the delay line 200 and output the driven signal as a DLL clock signal DLLCLK.

The replica delay circuit 400 may delay the output signal of the delay line 200 by a preset time, for example an internal time delay, and output the delayed signal as a feedback clock signal FBCLK.

The replica delay circuit 400 may include a delay circuit designed to have a delay time corresponding to an internal delay time of the semiconductor apparatus to which the synchronization circuit is applied.

The division circuit 500 may generate a divided feedback clock signal FBCLK_DV by dividing the feedback clock signal FBCLK at a division ratio which is set according to a division ratio control signal CTRL_DR.

The division ratio control signal CTRL_DR may have a value which is set according to one or more of the operation characteristics of a system to which the synchronization circuit 100 is to be applied, for example, operation voltage, temperature, and operation frequency.

The division ratio control signal CTRL_DR may be set to a desired value according to a test mode signal or a fuse set.

For example, the division ratio control signal CTRL_DR may be generated as a first value (for example, ‘00’), a second value (for example, ‘01’), a third value (for example, ‘10’), or a fourth value (for example, ‘11’).

The phase detection circuit 600 may generate a phase detection signal PDOUT by detecting the phase of the divided feedback clock signal FBCLK_DV transmitted through a signal line 501, based on the reference clock signal REFCLK.

The delay line control circuit 700 may control the delay time of the delay line 200 according to the phase detection signal PDOUT and the divided feedback clock signal FBCLK_DV transmitted through the signal line 501.

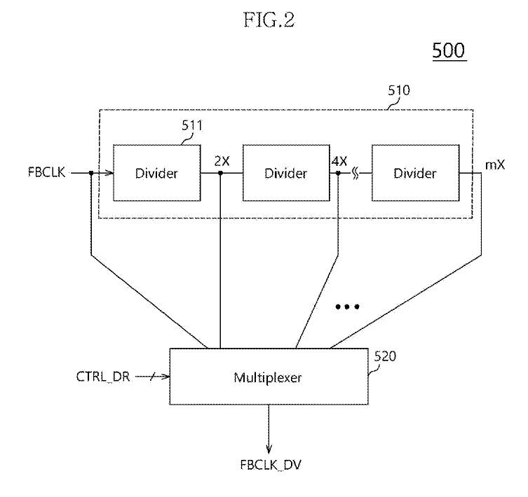

As illustrated in FIG. 2, the division circuit 500 may include a divider array 510 and a multiplexer 520.

The divider array 510 may include a plurality of dividers 511.

The plurality of dividers 511 may generate divided clock signals 2X, 4X, . . . , mX by dividing the feedback clock signal FBCLK or outputs of previous dividers 511, respectively.

At this time, 2X may represent a signal obtained by dividing the feedback clock signal FBCLK by 2, and 4X may represent a signal obtained by dividing the feedback clock signal FBCLK by 4. In this way, mX may represent a signal obtained by dividing the feedback clock signal FBCLK by m.

The multiplexer 520 may output one of the divided clock signals 2X, 4X, . . . , mX or the feedback clock signal FBCLK as the divided feedback clock signal FBCLK_DV according to the value of the division ratio control signal CTRL_DR.

For example, when the division ratio control signal CTRL_DR has the first value of ‘00’, the multiplexer 520 may output the feedback clock signal FBCLK as the divided feedback clock signal FBCLK_DV.

When the division ratio control signal CTRL_DR has the second value of ‘01’, the multiplexer 520 may output the divided clock signal 2X among the divided clock signals 2X, 4X, . . . , mX as the divided feedback clock signal FBCLK_DV.

When the division ratio control signal CTRL_DR has the fourth value of ‘11’, the multiplexer 520 may output the divided clock signal 8X among the divided clock signals 2X, 4X, . . . , mX as the divided feedback clock signal FBCLK_DV when m=8.

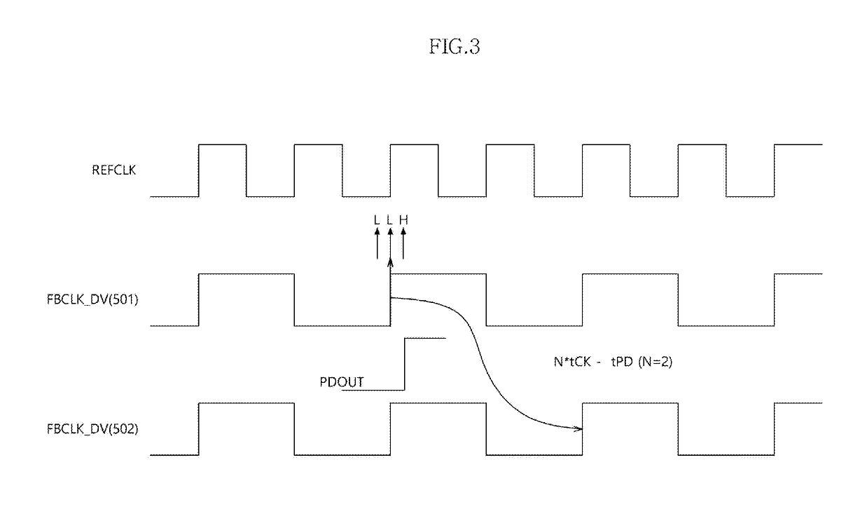

As illustrated in FIG. 3, the phase detection circuit 600 of the synchronization circuit 100 according to the present embodiment may generate the phase detection signal PDOUT by detecting a rising edge of the divided feedback clock signal FBCLK_DV transmitted through the signal line 501, based on a rising edge of the reference clock signal REFCLK.

The delay line control circuit 700 may increase or decrease the delay time of the delay line 200 according to the value of the phase detection signal PDOUT, where the phase detection signal PDOUT may be based on a rising edge of the divided feedback clock signal FBCLK_DV transmitted through the signal line 502.

In the present embodiment, the delay line control circuit 700 may control the delay time of the delay line 200 according to a divided feedback clock signal FBCLK_DV obtained by dividing the feedback clock signal FBCLK by N.

Thus, a delay compensation operation timing margin, that is, a timing margin between the phase detection signal PDOUT and the divided feedback clock signal FBCLK_DV may be set to (N*tCK-tPD).

FIG. 3 illustrates the case in which N is set 2 (N=2). In this case, a delay compensation operation timing margin may be set to (2*tCK-tPD). When N=4, a delay compensation operation timing margin may be set to (4*tCK-tPD).

At this time, tCK represents a time corresponding to one cycle of the reference clock signal REFCLK, and tPD represents a propagation delay time of the phase detection circuit 600.

According to the present embodiment, the synchronization circuit 102 may set the division ratio control signal CTRL_DR to a desired value according to a system operation characteristic. Further, the synchronization circuit 102 may adjust the division ratio of the feedback clock signal FBCLK, thereby performing a delay compensation operation with a sufficient timing margin.

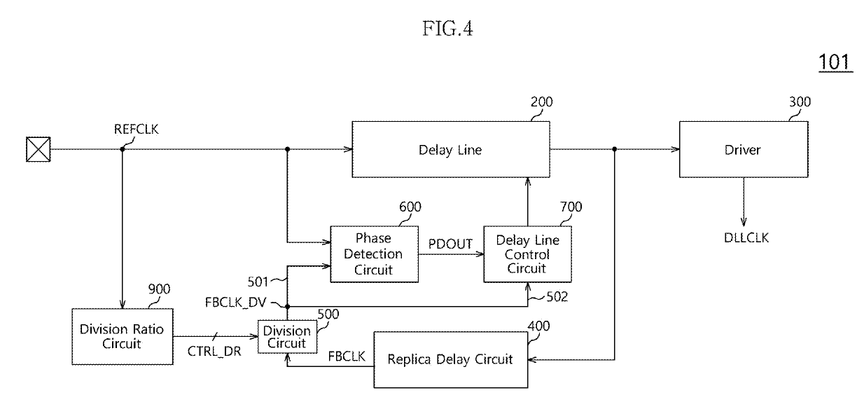

As illustrated in FIG. 4, a synchronization circuit 101 according to another embodiment may include a delay line 200, a driver 300, a replica delay circuit 400, a division circuit 500, a phase detection circuit 600, a delay line control circuit 700 and a division ratio control circuit 900.

The delay line 200 may delay a reference clock signal REFCLK.

The driver 300 may drive an output signal of the delay line 200 and output the driven signal as a DLL clock signal DLLCLK.

The replica delay circuit 400 may delay the output signal of the delay line 200 by a preset time, for example an internal delay time, and output the delayed signal as a feedback clock signal FBCLK.

The replica delay circuit 400 may include a delay circuit designed to have a delay time corresponding to an internal delay time of the semiconductor apparatus.

The division circuit 500 may generate a divided feedback clock signal FBCLK_DV by dividing the feedback clock signal FBCLK at a division ratio which is set according to a division ratio control signal CTRL_D R.

The division circuit 500 may be configured in the same manner as FIG. 2.

The phase detection circuit 600 may generate a phase detection signal PDOUT by detecting the phase of the divided feedback clock signal FBCLK_DV transmitted through a signal line 501, based on the reference clock signal REFCLK.

The delay line control circuit 700 may control the delay time of the delay line 200 according to the phase detection signal PDOUT and the divided feedback clock signal FBCLK_DV transmitted through a signal line 502.

The division ratio control circuit 900 may detect the frequency of the reference clock signal REFCLK, and generate at least one division ratio control signal CTRL_DR having a value based on the detected frequency.

The division ratio control circuit 900 may compare the detected frequency of the reference clock signal REFCLK to a plurality of reference values, and generate division ratio control signals CTRL_DR having different values.

The division ratio control circuit 900 may include a frequency detector (not illustrated) and a comparator (not illustrated).

For example, when the frequency of the reference clock signal REFCLK is equal to or less than a first reference value, a second reference value, a third reference value or a fourth reference value, the division ratio control signal CTRL_DR may be generated as a first value (for example, ‘00’), a second value (for example, ‘01’), a is third value (for example, ‘10’) or a fourth value (for example, ‘11’).

As described with reference to FIG. 2, the division circuit 500 may output the feedback clock signal FBCLK or one of the divided clock signals 2X, 4X, . . . , mX as the divided feedback clock signal FBCLK_DV according to the value of the division ratio control signal CTRL_D R.

The synchronization circuit 101 according to the present embodiment may directly detect the frequency of the reference clock signal REFCLK, set the value of the division ratio control signal CTRL_DR to a different value according to the detected frequency, and adjust the division ratio of the feedback clock signal FBCLK, thereby performing a delay compensation operation with a sufficient timing margin.

As described with reference to FIG. 3, the synchronization circuit 101 according to the present embodiment may have a delay compensation operation timing margin of (N*tCK-tPD) or a timing margin between the phase detection signal PDOUT and the divided feedback clock signal FBCLK_DV.

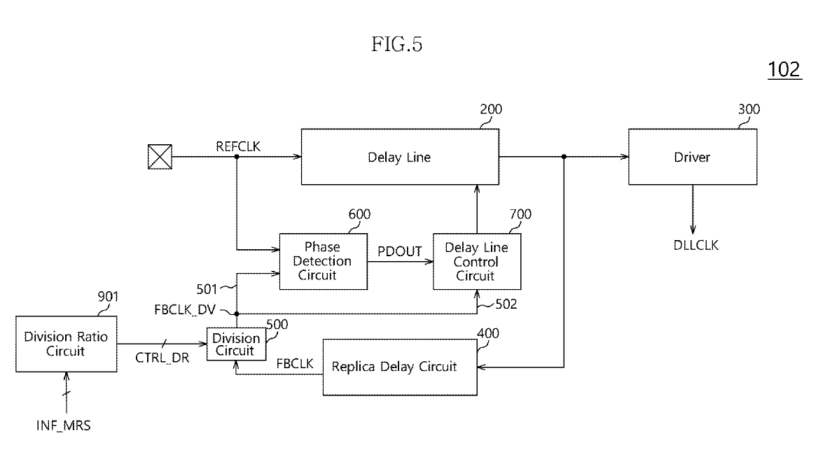

As illustrated in FIG. 5, a synchronization circuit 102 according to another embodiment may include a delay line 200, a driver 300, a replica delay circuit 400, a division circuit 500, a phase detection circuit 600, a delay line control circuit 700 and a division ratio control circuit 901.

The delay line 200 may delay a reference clock signal REFCLK.

The driver 300 may drive an output signal of the delay line 200 and output the driven signal as a DLL clock signal DLLCLK.

The replica delay circuit 400 may include a delay circuit designed to delay the output signal of the delay line 200 by a preset time and output the delayed signal as a feedback clock signal FBCLK.

The replica delay circuit 400 may include a delay circuit which may delay the output signal a time corresponding to an internal delay time of the semiconductor apparatus.

The division circuit 500 may generate a divided feedback clock signal FBCLK_DV by dividing the feedback clock signal FBCLK at a division ratio which is set according to a division ratio control signal CTRL_DR.

The division circuit 500 may be configured in the same manner as FIG. 2.

The phase detection circuit 600 may generate a phase detection signal PDOUT by detecting the phase of the divided feedback clock signal FBCLK_DV transmitted through a signal line 501, based on the reference clock signal REFCLK.

The delay line control circuit 700 may control the delay time of the delay line 200 according to the phase detection signal PDOUT and the divided feedback clock signal FBCLK_DV transmitted through a signal line 502.

The division ratio control circuit 901 may generate the division ratio control signal CTRL_DR according to a system setting information INF_MRS.

The system setting information INF_MRS may be outputted from a mode register set MRS, and include the frequency information of an input frequency or the reference clock signal REFCLK.

The division ratio control circuit 901 may determine to which range the frequency value of the reference clock signal included in the system setting information INF_MRS belongs among a plurality of ranges, and generate division ratio control signals CTRL_DR having different values from each other.

For example, when the frequency of the reference clock signal REFCLK is included in a first range, a second range, a third range or a fourth range, the division ratio control signal CTRL_DR may be generated as a first value (for example, ‘00’), a second value (for example, ‘01’), a third value (for example, ‘10’) or a fourth value (for example, ‘11’).

As described with reference to FIG. 2, the division circuit 500 may output the feedback clock signal FBCLK or one of the divided clock signals 2X, 4X, . . . , mX as the divided feedback clock signal FBCLK_DV according to the value of the division ratio control signal CTRL_D R.

The synchronization circuit 102 according to the present embodiment may determine to which range the frequency of the reference cock signal REFCLK included in the system setting information INF_MRS belongs among the plurality of preset ranges, set the division ratio control signal CTRL_DR to a different value, and adjust the division ratio of the feedback clock signal FBCLK, thereby is performing a delay compensation operation with a sufficient timing margin.

Furthermore, as according to an embodiment described with reference to FIG. 3, the synchronization circuit 102 may have a delay compensation operation timing margin of (N*tCK-tPD) or a timing margin between the phase detection signal PDOUT and the divided feedback clock signal FBCLK_DV.

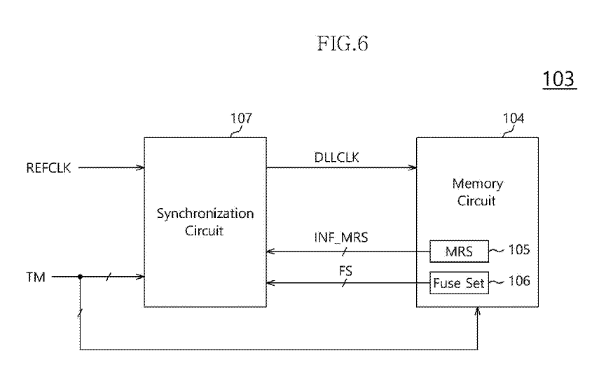

As illustrated in FIG. 6, a semiconductor apparatus 103 according to an embodiment may include a memory circuit 104 and a synchronization circuit 107.

The memory circuit 104 may perform a data output operation according to a DLL clock signal DLLCLK.

The memory circuit 104 may have internal operation-related settings which are controlled according to a test mode signal TM.

The memory circuit 104 may include DRAM, FLASH RAM, or SSD.

The memory circuit 104 may include a mode register set 105 and a fuse set 106.

The mode register set 105 may store information related to the operation characteristics of the memory circuit 104, for example, operation voltage, temperature, and operation frequency.

The mode register set 105 may output the stored information as system setting information INF_MRS, which is provided the memory circuit 104 to which the synchronization circuit 107 is applied.

The fuse set 106 may store various pieces of setting information for operation of the memory circuit 104, through a fuse cutting or rupture operation.

The fuse set 106 may output the stored information as a fuse signal FS.

The synchronization circuit 107 may selectively employ one or more of the synchronization circuit 100 of FIG. 1, the synchronization circuit 101 of FIG. 4, and the synchronization circuit 102 of FIG. 5.

The synchronization circuit 107 may generate the DLL clock signal DLLCLK by delaying a reference clock signal REFCLK through a delay line, detect the phase of the feedback clock signal FBCLK based on a divided feedback clock signal FBCLK_DV obtained by dividing a feedback clock signal FBCLK, and adjust a delay time of the delay line according to the divided feedback clock signal FBCLK_DV.

The synchronization circuit 107 may adjust the division ratio of the feedback clock signal FBCLK according to the test mode signal TM, the system setting information INF_MRS, the fuse signal FS, or the frequency of the reference clock signal REFCLK detected thereby. Thus, the synchronization circuit 107 may generate the DLL clock signal DLLCLK by performing a stable delay compensation operation in a state where a sufficient timing margin is secured.

While certain embodiments have been described above, it will be understood by those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

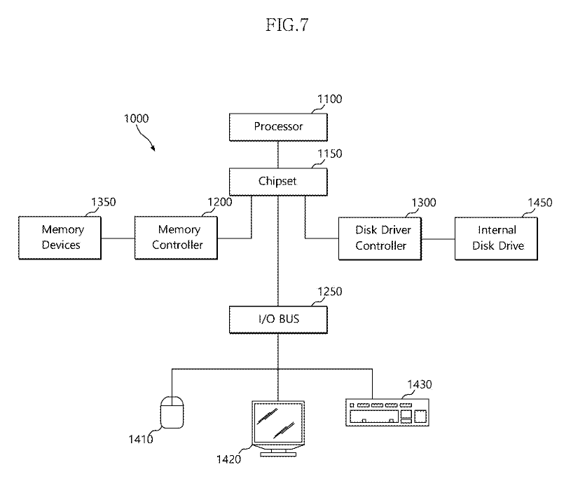

The semiconductor devices and/or a synchronization circuits discussed above (see FIGS. 1-6) are particularly useful in the design of memory devices, processors, and computer systems. For example, referring to FIG. 7, a block diagram of a system employing a semiconductor device and/or a synchronization circuit in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor device and/or a synchronization circuit as discussed above with reference to FIGS. 1-6. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device and/or a synchronization circuit as discussed above with relation to FIGS. 1-6, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 7 is merely one example of a system 1000 employing a semiconductor device and/or a synchronization circuit as discussed above with relation to FIGS. 1-6. In alternate embodiments, such as, for example but not limited to, cellular phones or digital cameras, the components may differ from the embodiments is illustrated in FIG. 7.

What is claimed is:

1. A synchronization circuit comprising:
a delay line configured to delay a reference clock signal;
a division circuit configured to generate a divided feedback clock signal by dividing a feedback clock signal at a division ratio which is set according to a division ratio control signal;
a phase detection circuit configured to generate a phase detection signal by detecting the phase of the divided feedback clock signal based on the reference clock signal; and
a delay line control circuit configured to control a delay time of the delay line according to the phase detection signal and the divided feedback clock signal.

2. The synchronization circuit according to claim 1, further comprising a replica delay circuit configured to delay an output signal of the delay line by an internal delay time of a semiconductor apparatus to which the synchronization circuit is applied, and output the delayed signal as the feedback clock signal.

3. The synchronization circuit according to claim 1, wherein the division ratio control signal has a value which is set according to one or more of an operation voltage, temperature and operation frequency of a system to which the synchronization circuit is to be applied.

4. The synchronization circuit according to claim 1, wherein the division ratio control signal is set through a test mode signal or fuse set.

5. The synchronization circuit according to claim 1, wherein the division circuit comprises:
a plurality of dividers each configured to generate a divided clock signal by dividing the feedback clock signal or an output of the previous divider; and
a multiplexer configured to output one of the divided clock signals or the feedback clock signal as the divided feedback clock signal according to the value of the division ratio control signal.

6. The synchronization circuit according to claim 1, further comprising a division ratio control circuit configured to detect the frequency of the reference clock signal, and generate the division ratio control signals having different values set according to the detected frequency.

7. The synchronization circuit according to claim 1, further comprising a division ratio control circuit configured to generate the division ratio control signal according to system setting information provided from a system to which the synchronization circuit is applied.

8. The synchronization circuit according to claim 7, wherein the division ratio control circuit determines to which range the frequency value of the reference clock signal included in the system setting information belongs among a plurality of ranges, and generates the division ratio control signals having different values.

9. A semiconductor apparatus comprising:
a memory circuit configured to perform a data output operation according to a DLL (Delay Locked Loop) clock signal; and
a synchronization circuit configured to generate the DLL clock signal by delaying a reference clock signal through a delay line, and adjust a delay time of the delay line according to a divided feedback clock signal obtained by dividing the feedback clock signal.

10. The semiconductor apparatus according to claim 9, wherein the memory circuit comprises one or more of:
a mode register set configured to store operation characteristic information of the memory circuit, and output the stored information as system setting information; and
a fuse set configured to store setting information related to operation of the memory circuit, and output the stored information as a fuse signal.

11. The semiconductor apparatus according to claim 10, wherein the synchronization circuit is configured to generate the divided feedback clock signal by adjusting the division ratio of the feedback clock signal according to a test mode signal, the system setting information, the fuse signal or the frequency of the reference clock signal detected by the synchronization circuit.

12. The semiconductor apparatus according to claim 11, wherein the synchronization circuit comprises:
a division circuit configured to generate the divided feedback clock signal by dividing the feedback clock signal at a division ratio which is set according to a division ratio control signal;
a phase detection circuit configured to generate a phase detection signal by detecting the phase of the divided feedback clock signal based on the reference clock signal; and
a delay line control circuit configured to control a delay time of the delay line according to the phase detection signal and the divided feedback clock signal.

13. The semiconductor apparatus according to claim 12, wherein the division ratio control signal has a value which is set according to one or more of an operation voltage, temperature and operation frequency of the semiconductor apparatus.

14. The semiconductor apparatus according to claim 12, wherein the division ratio control signal is set according to the test mode signal or the fuse signal.

15. The semiconductor apparatus according to claim 12, wherein the synchronization circuit further comprises a replica delay circuit configured to delay an output signal of the delay line by an internal delay time of the semiconductor apparatus, and output the delayed signal as the feedback clock signal.

16. The semiconductor apparatus according to claim 12, wherein the division circuit comprises:
a plurality of dividers each configured to generate a divided clock signal by dividing the feedback clock signal or an output of the previous divider; and
a multiplexer configured to output one of the divided clock signals or the feedback clock signal as the divided feedback clock signal according to the value of the division ratio control signal.

17. The semiconductor apparatus according to claim 12, wherein the synchronization circuit further comprises a division ratio control circuit configured to detect the frequency of the reference clock signal, and generate the division ratio control signals having different values according to the detected frequency.

18. The semiconductor apparatus according to claim 12, wherein the synchronization circuit further comprises a division ratio control circuit configured to generate the division ratio control signal according to the system setting information.

19. The semiconductor apparatus according to claim 18, wherein the division ratio control circuit determines to which range the frequency value of the reference clock signal included in the system setting information belongs among a plurality of ranges, and generates the division ratio control signals having different values.

20. The semiconductor apparatus according to claim 12, wherein the phase detection signal is based on a rising edge of the divided feedback clock signal, and the divided feedback clock signal is obtained by dividing the feedback clock signal.
